(19) United States
(12) Patent Application Publication
(10) Pub. No.: US 2026/0136480 A1
(43) Pub. Date: May 14, 2026

(54) FLEXIBLE DISPLAY WITH LAYERED STRUCTURE

(71) Applicant: JAMES KANG, Las Vegas, NV (US)

(72) Inventor: JAMES KANG, Las Vegas, NV (US)

(21) Appl. No.: 19/119,874

(22) PCT Filed: Oct. 11, 2023
(86) PCT No.: PCT/US2023/076516

§ 371 Date: Apr. 10, 2025

(51) Int. Cl. H05K 5/02; H10K 59/12; H10K 59/124; H10K 102/00

(52) U.S. Cl. CPC H05K 5/0217; H10K 59/1201; H10K 59/124; H10K 2102/311

(57) ABSTRACT

Embodiments relate to a flexible display apparatus comprising plurality of layers wherein each layer is connected to at least one another layer at a predetermined position forming a connection, wherein the flexible display apparatus is part of a display of an electronic device, and wherein each layer of the plurality of layers comprises a rotational degree of freedom and glides relative to an adjacent layer of the plurality of layers about an axis of fold or roll when the display is folded or rolled.

### RELATED APPLICATIONS

This patent application is a National Stage Entry of PCT/US2023/076516 filed on Oct. 11, 2022, which claims the benefit under 35 U.S.C § 119 of U.S. Provisional Application No. 63/415,016, filed on Oct. 11, 2022, which is hereby incorporated by reference in its entirety.

### FIELD OF INVENTION

This disclosure relates to the field of electronic devices, and more particularly to a flexible display apparatus capable of being bent, folded along an axis, or rolled.

### BACKGROUND

In this section prior art is cited:

“In a general rollable display apparatus, a flexible display panel may be rolled on a housing. In this case, too much stress or nicks may occur in a portion of the flexible display panel, so defects may occur at pixels provided in the portion of the flexible display panel.” [U.S. Pat. No. 9,710,020B2, titled “Rollable display apparatus”]

“Particularly, to improve a user's convenience, the display apparatuses having a relatively smaller size and lighter weight are being developed.

As a measure for this trend, flexible display apparatuses that are foldable or bendable are actively being developed in various types. In addition, ways for more improving bending strength and flexibility of the flexible display apparatuses are being requested.” [U.S. Pat. No. 10,459,489B2 titled “Display panel and display apparatus including the same”]

“Foldable displays are recently developed displays that may be very thin and made of solid-state semiconductor devices. In pre-existing Organic Light Emitting Diode (“OLED”) displays, the semiconductor device section is generally 100 to 500 nanometers thick and comprises at least one layer of an organic material. The semiconductor device portion of the pre-existing displays is generally supported by a substrate which is made of clear plastic, glass, or very thin metallic foil. The primary function of the substrate is for manufacturing purposes (for deposition and application of the organic layers); otherwise, the substrate does not provide any structural benefit.

One advantage of OLEDs is their ability to be rolled or folded into compact shapes which may be an advantage for portable electronic devices, whether hand-held smartphones or large area wall-mountable displays. However, the OLEDs do not have structural stability and rigidity to maintain a flat shape, especially after multiple folding and/or rolling. This inability to remain flat may adversely affect their optimal function with the increasing demand for high definition display. The common materials used for the substrate of pre-existing display structures, such as plastics, aluminum, and glass, may not provide enough strength, rigidity, and durability without increasing the bulkiness of the display structures, which in turn adversely impacts the flexibility of OLED display.” [U.S. Pat. No. 10,280,493B2, titled “Foldable display structures”]

Therefore, there is a need for a flexible display apparatus/supporting structure, used for displays, with a combination of strength, zero memory, and the ability to accommodate tight bend radius.

### SUMMARY

The following is a summary to provide a basic understanding of one or more embodiments described herein. This summary is not intended to identify key or critical elements or delineate any scope of the different embodiments and/or any scope of the claims. The sole purpose of the summary is to present some concepts in a simplified form as a prelude to the more detailed description presented herein.

In view of the foregoing, the Inventor has recognized and appreciated the advantages of providing improved structural support to OLEDs to provide and enhance their flatness and durability while preserving their flexibility and ability to be folded or rolled into compact shapes for multiple uses.

According to an embodiment, it is a flexible display apparatus comprising plurality of layers wherein each layer is connected to at least one other layer at a predetermined position forming a connection, wherein the flexible display apparatus is part of a display of an electronic device, and wherein each layer of the plurality of layers comprises a rotational degree of freedom and glides relative to an adjacent layer of the plurality of layers about an axis of fold or roll when the display is folded or rolled.

According to an embodiment of the flexible display apparatus, each layer of the plurality of layers comprises a material having an elastic limit of at least 1.5% strain.

According to an embodiment of the flexible display apparatus, a flexible silica glass surface forms a first surface layer towards a display side and supported by a second surface layer with an amorphous sheet.

According to an embodiment of the flexible display apparatus, the amorphous sheet comprises either silica or alloys.

According to an embodiment of the flexible display apparatus, an Organic Light-Emitting Diode (OLED) is printed on the flexible silica glass surface.

According to an embodiment of the flexible display apparatus, the flexible silica glass surface is firmly bonded to one or more layers of amorphous alloy along a flex zone.

According to an embodiment of the flexible display apparatus, the flexible silica glass surface is firmly bonded to one or more layers of silica along a flex zone.

According to an embodiment of the flexible display apparatus, at least a layer of the plurality of layers comprises an amorphous material.

According to an embodiment of the flexible display apparatus, the amorphous material comprises iron based amorphous ribbons.

According to an embodiment of the flexible display apparatus, the amorphous material comprises silica based glass sheets.

According to an embodiment of the flexible display apparatus, the plurality of layers of the flexible display apparatus forms a spring structure.

According to an embodiment of the flexible display apparatus, the iron based amorphous ribbons comprise iron in a first range of 84-100%, silicon in a second range of 0-10%, boron in a third range of 0-5%, and manganese in a fourth range of 0-2%.

According to an embodiment of the flexible display apparatus, the iron based amorphous ribbons comprise iron in a first range of 0-100%, cobalt in a second a second range of 0-85%, Nickel in a third range of 0-50%, silicon in a fourth range of 0-10%, molybdenum in a fifth range of 0-8%, boron in a sixth range of 0-5%, and manganese in a seventh range of 0-2%.

According to an embodiment of the flexible display apparatus, the amorphous material comprises an amorphous alloy that has an elastic strain limit of at least 1.5% selected from (Zr,Ti)a(Ni,Cu,Fc)b(Be,Al,Si,B)c wherein a=30-75; b=5-60 & c=0-50 in atomic percentages; (Zr,Ti)a(Ni,Cu)b(Be)c wherein a=40-75; b=5-50; & c=5-50 in atomic percentages; (Zr,Ti)a(Ni,Cu)b(Be)c wherein a=40-65; b=7.5-35; & c=10-37.5 in atomic percentages; and (Zr)a(Nb,Ti)b(Ni,Cu)c(Al)d wherein a=45-65; b=0-10; c=20-40; & d=7.5-15 in atomic percentages.

According to an embodiment of the flexible display apparatus, the amorphous alloy comprises a Zr-based, a Ti-based, a Zr—Ti-based, an Fe-based, or combinations thereof, amorphous alloy.

According to an embodiment of the flexible display apparatus, the amorphous alloy is at least substantially free of Be.

According to an embodiment of the flexible display apparatus, the amorphous alloy further comprises a plurality of crystalline precipitates.

According to an embodiment of the flexible display apparatus, at least one of the plurality of layers comprises a plurality of structural components comprising wires, strips, fibers, ribbons, or combinations thereof, wherein the plurality of structural components is configured to provide structural stability and rigidity to maintain a flat shape of the display after multiple folding and unfolding or rolling and unrolling of the display.

According to an embodiment of the flexible display apparatus, the plurality of the structural components comprises a series of horizontally aligned strips.

According to an embodiment of the flexible display apparatus, the plurality of the structural components comprises a mesh of horizontally and longitudinally aligned fibers.

According to an embodiment of the flexible display apparatus, at least one of the plurality of the structural components comprises (i) fibers having a diameter of between about 0.01 mm and about 0.5 mm, or (ii) ribbons having a thickness of about 0.023 mm and a width of about 2 mm and about 213 mm.

According to an embodiment of the flexible display apparatus, the connection is a rigid connection.

According to an embodiment of the flexible display apparatus, the connection comprises a mechanical joint comprising one of a spot welding, a fastening joint, and a rivet.

According to an embodiment of the flexible display apparatus, the connection comprises a mechanical joint comprising a telescopic sliding joint.

According to an embodiment of the flexible display apparatus, the predetermined position is configured such that varying the predetermined position varies a degree of free gliding.

According to an embodiment of the flexible display apparatus, the display comprises at least one organic light emitting diode; wherein at least one of the plurality of layers comprises at least one amorphous alloy; and wherein the display remains at least substantially flat after folding and unfolding multiple times.

According to an embodiment of the flexible display apparatus, the flexible display apparatus is part of one or more of a mobile phone, a smart phone, a personal digital assistance, a computer, a television, a wall-mountable display.

According to an embodiment of the flexible display apparatus, each layer of the plurality of layers has a different thickness.

According to an embodiment of the flexible display apparatus, each layer of the plurality of layers has the same thickness.

According to an embodiment of the flexible display apparatus, a first layer of the plurality of layers closest to a display side has a first thickness different from a second layer of the plurality of layers farthest from the display side having second thickness, wherein the first thickness is smaller than the second thickness, and wherein an elastic limit of a first material of the first layer and a second material of the second layer is at least 1.5% strain.

According to an embodiment of the flexible display apparatus, a lubrication mechanism is positioned between adjacent layers, said lubrication mechanism configured to reduce friction and promote a free movement of said layers relative to each other.

According to an embodiment of the flexible display apparatus, the lubrication mechanism comprises a dry lubricant.

According to an embodiment of the flexible display apparatus, the lubrication mechanism comprises a liquid lubricant contained within sealed channels between adjacent layers.

According to an embodiment of the flexible display apparatus, a magnetic field is used to hold the plurality of layers in stable position, until a sufficient force is applied to free the layers.

According to an embodiment, it is a display comprising a flexible display apparatus, wherein the flexible display apparatus comprises a plurality of layers wherein each layer is connected to at least one other layer at a predetermined position forming a connection, and wherein each layer of the plurality of layers comprises a rotational degree of freedom and glides relative to an adjacent layer of the plurality of layers about an axis of fold or roll when the display is folded or rolled.

According to an embodiment of the display, the display is operable to be a secondary display to an electronic device.

According to an embodiment of the display, the display is operable to be an extension of an existing display to an electronic device.

According to an embodiment of the display, the display is operable to be connected via a wireless connection or a wired connection.

According to an embodiment of the display, the display is operable to be interconnected with a second display of similar nature to form a continuous display.

According to an embodiment of the display, the display is operable for wireless charging.

According to an embodiment of the display, the display is a touch sensitive display.

According to an embodiment, it is a method for manufacturing comprising selecting number of layers to form a plurality of layers based on a predetermined thickness of a flexible display apparatus; selecting the thickness of each of the layers of the plurality of layers; selecting material for each layer such that an elastic strain limit of the material is at least 1.5%; positioning the layers in a desired configuration; and securely connecting the layers such that each layer is connected to at least one other layer at a predetermined position forming a connection; and wherein the flexible display apparatus is part of a display of an electronic device; and wherein each layer of the plurality of layers comprises a rotational degree of freedom and glides relative to an adjacent layer of the plurality of layers about an axis of fold or roll when the display is folded or rolled.

According to an embodiment of the method for manufacturing, the connection is a rigid connection point.

According to an embodiment of the method for manufacturing, the connection comprises a mechanical joint comprising one of a spot welding, a fastening joint, and a rivet.

According to an embodiment of the method for manufacturing, the connection comprises a mechanical joint comprising a telescopic sliding joint.

### BRIEF DESCRIPTION OF THE FIGURES

Aspects of the present invention will now be described in more detail, with reference to the appended drawings showing exemplary embodiments of the present invention, in which:

FIG. 1A shows a foldable screen/display of a smart phone according to an embodiment.

FIG. 1B shows a roll up screen/display according to an embodiment.

FIG. 1C shows a creased surface along the flex zone of the current foldable displays in the market according to an embodiment.

FIG. 2 shows a single spring's strain on the inner and outer surface according to an embodiment.

FIG. 3 shows a single solid spring and a strain on the inner and outer surface according to an embodiment.

FIG. 4 shows a layered spring and a strain on the inner and outer surface according to an embodiment.

FIG. 5 shows a table comparing the strain in a solid spring and a layered spring according to an embodiment.

FIG. 6 shows a first example for a layered pattern for a supporting structure according to an embodiment.

FIG. 7 shows a second example for a layered pattern for a supporting structure according to an embodiment.

FIG. 8 shows a first example for the chemistry of an Iron (Fe)-based amorphous Ribbons according to an embodiment.

FIG. 9 shows a second example for the chemistry of an Iron (Fe) based amorphous Ribbons according to an embodiment.

FIG. 10 shows dimensions of Iron (Fe) based amorphous Ribbons that are commercially available in the market according to an embodiment.

FIG. 11 shows properties of Silica glass by Schott® according to an embodiment.

FIG. 12 shows a roll up/foldable screen that can be used as an extension to the existing smart phone screen according to an embodiment.

FIG. 13 shows a roll up/foldable screen that can be used as an extension to the existing screen according to an embodiment.

FIG. 14 shows a roll up/foldable screen that can be used as an extension in various scenarios and for applications according to an embodiment.

FIG. 15 shows a lateral cross-section view schematically illustrating the internal structure of the display apparatus according to an embodiment.

FIG. 16 illustrates a display panel touched in the display apparatus, having the flexible structure according to an embodiment.

FIG. 17 shows a schematic of a first example foldable display structure according to an embodiment.

FIG. 18 shows a schematic of a second example foldable display structure according to an embodiment.

FIG. 19 shows a schematic of a third example foldable display structure according to an embodiment.

### DETAILED DESCRIPTION

### Definitions and General Techniques

For simplicity and clarity of illustration, the figures illustrate the general manner of construction. The description and figures may omit the descriptions and details of well-known features and techniques to avoid unnecessarily obscuring the present disclosure. The figures may exaggerate the dimensions of some of the elements relative to other elements to help improve understanding of embodiments of the present disclosure. The same reference numeral in different figures denotes the same element.

Although the detailed description herein contains many specifics for the purpose of illustration, a person of ordinary skill in the art will appreciate that many variations and alterations to the details are considered to be included herein. Accordingly, the embodiments herein are without any loss of generality to, and without imposing limitations upon, any claims set forth. The terminology used herein is for the purpose of describing particular embodiments only and is not limiting. Unless defined otherwise, all technical and scientific terms used herein have the same meaning as commonly understood by one with ordinary skill in the art to which this disclosure belongs.

Other specific forms may embody the present invention without departing from its spirit or characteristics. The described embodiments are in all respects illustrative and not restrictive. Therefore, the appended claims, rather than the description herein, indicate the scope of the invention. All variations which come within the meaning and range of equivalency of the claims are within their scope.

While this specification contains many specifics, these do not construe as limitations on the scope of the disclosure or of the claims, but as descriptions of features specific to particular implementations. A single implementation may implement certain features described in this specification in the context of separate implementations. Conversely, multiple implementations separately or in any suitable sub-combination may implement various features described herein in the context of a single implementation. Moreover, although features described herein are acting in certain combinations and even initially claimed as such, one or more features from a claimed combination may in some cases be excised from the combination, and the claimed combination may be directed to a sub-combination or variation of a sub-combination.

Similarly, while operations depicted herein in the drawings in a particular order to achieve desired results, this should not be understood as requiring that such operations be performed in the particular order shown or in sequential order or that all illustrated operations be performed to achieve desirable results. In certain circumstances, multitasking and parallel processing may be advantageous. Moreover, the separation of various system components in the implementations should not be understood as requiring such separation in all implementations, and it should be understood that the described program components and systems may be integrated together in a single software product or packaged into multiple software products.

Even though particular combinations of features are recited in the claims and/or disclosed in the specification, these combinations are not intended to limit the disclosure of possible implementations. Other implementations are within the scope of the claims. For example, the actions recited in the claims may be performed in a different order and still achieve desirable results. In fact, many of these features may be combined in ways not specifically recited in the claims and/or disclosed in the specification. Although each dependent claim may directly depend on only one claim, the disclosure of possible implementations includes each dependent claim in combination with every other claim in the claim set.

The present disclosure may be embodied in other specific forms without departing from its spirit or characteristics. The described embodiments are to be considered in all respects only as illustrative and not restrictive. The scope of the disclosure is, therefore, indicated by the appended claims rather than by the foregoing descriptions. All changes which come within the meaning and range of equivalency of the claims are to be embraced within their scope.

Unless otherwise defined herein, scientific, and technical terms used in connection with the present disclosure shall have meanings that are commonly understood by those of ordinary skill in the art. Further, unless otherwise required by context, singular terms shall include pluralities and plural terms shall include the singular.

The following terms and phrases, unless otherwise indicated, shall be understood to have the following meanings.

As used herein, the articles “a” and “an” used herein refer to one or to more than one (i.e., to at least one) of the grammatical object of the article. By way of example, “an element” means one element or more than one element. Moreover, usage of articles “a” and “an” in the subject specification and annexed drawings construe to mean “one or more” unless specified otherwise or clear from context to mean a singular form.

As used herein, the terms “example” and/or “exemplary” mean serving as an example, instance, or illustration. For the avoidance of doubt, such examples do not limit the herein described subject matter. In addition, any aspect or design described herein as an “example” and/or “exemplary” is not necessarily preferred or advantageous over other aspects or designs, nor does it preclude equivalent exemplary structures and techniques known to those of ordinary skill in the art.

As used herein, the terms “first,” “second,” “third,” and the like in the description and in the claims, if any, distinguish between similar elements and do not necessarily describe a particular sequence or chronological order. The terms are interchangeable under appropriate circumstances such that the embodiments herein are, for example, capable of operation in sequences other than those illustrated or otherwise described herein. Furthermore, the terms “include”, “have”, and any variations thereof, cover a non-exclusive inclusion such that a process, method, system, article, device, or apparatus that comprises a list of elements is not necessarily limiting to those elements, but may include other elements not expressly listed or inherent to such process, method, system, article, device, or apparatus.

As used herein, the terms “left”, “right”, “front”, “back”, “top”, “bottom”, “over”, “under”, and the like, in the description and in the claims, if any, are for descriptive purposes and not necessarily for describing permanent relative positions. The terms so used are interchangeable under appropriate circumstances such that the embodiments of the apparatus, methods, and/or articles of manufacture described herein are, for example, capable of operation in other orientations than those illustrated or otherwise described herein.

No element act, or instruction used herein is critical or essential unless explicitly described as such. Furthermore, the term “set” includes items (e.g., related items, unrelated items, a combination of related items and unrelated items, etc.) and may be interchangeable with “one or more”. Where only one item is intended, the term “one” or similar language is used. Also, the terms “has,” “have,” “having,” or the like are open-ended terms. Further, the phrase “based on” means “based, at least in part, on” unless explicitly stated otherwise.

As used herein, the terms “couple,” “coupled,” “couples,” “coupling,” and the like, refer to connecting two or more elements mechanically, electrically, and/or otherwise. Two or more electrical elements may be electrically coupled together, but not mechanically or otherwise coupled together. Coupling may be for any length of time, e.g., permanent, or semi-permanent or only for an instant. “Electrical coupling” includes electrical coupling of all types. The absence of the word “removably,” “removable,” and the like, near the word “coupled” and the like does not mean that the coupling, etc., in question is or is not removable.

As used herein, the terms “system,” “device,” “unit,” and/or “module” refer to a different component, component portion, or component of the various levels of the order. However, other expressions that achieve the same purpose may replace the terms.

As used herein, the term “or” means an inclusive “or” rather than an exclusive “or.” That is, unless specified otherwise, or clear from context, “X employs A or B” means any of the natural inclusive permutations. That is, if X employs A; X employs B; or X employs both A and B, then “X employs A or B” is satisfied under any of the foregoing instances.

As used herein, the term “approximately” can mean within a specified or unspecified range of the specified or unspecified stated value. In some embodiments, “approximately” can mean within plus or minus ten percent of the stated value. In other embodiments, “approximately” can mean within plus or minus five percent of the stated value. In further embodiments, “approximately” can mean within plus or minus three percent of the stated value. In yet other embodiments, “approximately” can mean within plus or minus one percent of the stated value.

As used herein, two or more elements or modules are “integral” or “integrated” if they operate functionally together. Two or more elements are “non-integral” if each element can operate functionally independently.

It will be understood that when an element, layer, region, or component is referred to as being “on,” “connected to,” or “coupled to” another element, layer, region, or component, it can be directly on, connected to, or coupled to the other element, other layer, other region, other component, or one or more intervening elements, layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or it is not the only element, and one or more intervening elements or layers may also be present between the two elements or layers.

The term “fold” as used herein refers to the action of bending or creasing the flexible display screen along a specific axis or hinge point to change its form factor. Foldable displays are to be designed to be flexible and capable of being folded or unfolded repeatedly without damaging the screen or affecting its functionality. This flexibility allows the display to transition between different configurations, such as a traditional flat-screen mode and a folded mode where the screen is partially or completely bent.

The term “Roll” as used herein refers to the action of winding or rolling up the flexible display screen around a cylindrical or rollable core or axis. Rollable displays are to be designed to be flexible and capable of being rolled and unrolled repeatedly without damaging the screen or impacting its functionality. This flexibility allows the display to transition between different form factors, such as a traditional flat-screen mode and a rolled-up mode where the display is compactly stored or partially rolled, offering users convenience and portability.

The term “Hysteresis” refers to the phenomenon where the response of a material to an external force or stimulus is delayed or lags behind the cause of the stimulus. In other words, the material's behavior depends not only on the current stimulus but also on its past history. For example, in the context of stress and strain in a material, hysteresis is observed when the stress-strain curve for loading (increasing stress) is different from the curve for unloading (decreasing stress). This difference indicates that the material doesn't return to its original state when the load is removed; it retains some deformation or memory of the past loading.

The term “Hysteresis loss” in the context of flex cycles refers to the energy dissipation or loss that occurs when a material or component is subjected to repeated flexing or bending. This loss occurs because not all of the energy applied to deform the material during each cycle is recovered when the material returns to its original shape. Instead, some of the energy is converted into heat or other forms of internal energy within the material.

The term “Zero memory” refers to materials or systems that return to their original state or position after being subjected to external forces or deformations. In this context, “zero memory” suggests that there is no hysteresis or lag in the material's response, and it returns precisely or almost close to its initial condition. Shape memory alloys, like Nitinol, are an exception where the term “zero memory” is used. In these materials, when heated above a certain temperature (the austenite finish temperature), they return precisely to their original shape after being deformed, exhibiting minimal hysteresis.

The term “display structure” or “support structure” as used herein refers to the structure that provides rigidity in flexible displays and is also called the “substrate” or “backplane.” The choice of material for the substrate or backplane is crucial, as it needs to be rigid to maintain the structural integrity of the display while still allowing for flexibility to some degree. This is also referred to as display apparatus in this disclosure.

Problem defined: As smart phones have effectively taken over many of the traditional functions of computers, the amount of information that can be viewed is limited by the size of the display. The global average functions are expected to increase dramatically over the next 20 years, which necessitates larger display size.

An iPad® does not fit in most pockets and purses. Even most smart phones have settled between 6″ to 7″ screen size.

The need to offer displays of variable geometry that can easily fold or roll up and yet open up to the size of an iPad® has been the ultimate holy grail.

The current Organic light-emitting diode (OLED) displays develop memory when articulated repeatedly and as shown by Samsung®'s latest phones, this memory results in visible creases along the flexing surface.

Presently, the materials supporting the OLED display do not have the combination of strength, zero memory, and most importantly the ability to accommodate tight bend radii of less than 2.0 mm.

Flexible Display (FD) devices can be divided into two categories: (i) Two rigid surfaces connected by a flex zone and (ii) One large surface that rolls up.

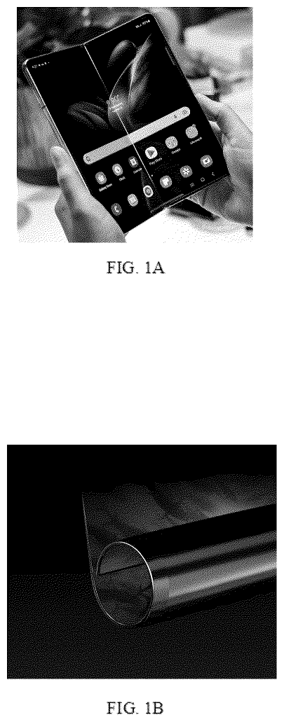

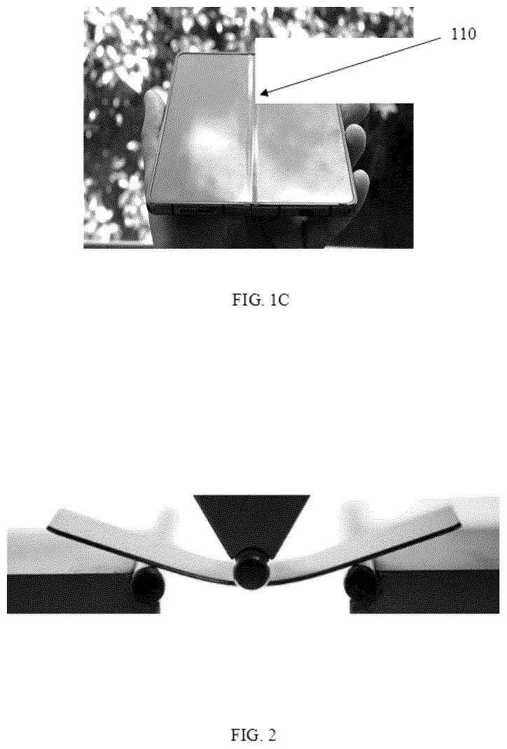

Two rigid surfaces connected by a flex zone: FIG. 1A shows a foldable screen/display of a smart phone according to an embodiment. One large display that is folded along a limited flex zone, similar to Samsung® phones currently on the market. This function of the flexible area is that of a hinge and the radius of the flexible surface can be 1.5 mm to 3.0 mm.

One large surface that rolls up: FIG. 1B shows a roll up screen/display according to an embodiment. Another application is displays that roll up with a radius of 10.0 mm to 30.0 mm. As the display also functions as an input device with touch pad function, a certain level of structural integrity and ultra-thin geometry is necessary.

FIG. 1C shows a creased surface along the flex zone of a current foldable display in the market according to an embodiment. The display reveals a creased surface 110 along the flex zone. This Flex zone is also prone to cracks.

A supporting structure behind OLED display must meet three key properties:
i. Highest strength to volume.
ii. Close to ZERO Memory or Hysteresis Loss through flex cycles.
iii. Available in Sheet or Foil thicknesses:
   Between 0.02 mm to 0.05 mm for two flat surfaces folding (similar to SS phones).
   Between 0.1 mm to 0.5 mm for roll up display.

A flexible support structure must have sufficient strength to articulate the OLED and other supporting brackets and surfaces to a flat position and be able to provide sufficient structural integrity to accommodate touchscreen function. Amorphous Alloys have a 10× strength to volume advantage vs. silica glass and 2× strength to volume advantage vs. Nitinol Alloys. As shown herein, volume (density) and strain limit have a linear effect on the radius of the bend that can be achieved. Thus, strength to weight ratio greatly favors foils made of Amorphous alloys.

Amorphous alloys have perfect memory and no hysteresis loss. This allows the entire articulating surface to return to its original position.

A single thick amorphous sheet might function well to maintain the flat surface and structural rigidity. However, as amorphous metallic sheets have elastic limits of approximately 2.0%, the strain load on the outer surface is directly proportional to the radius of the curve in relation to the “t” (thickness of the spring). In an embodiment, a combined thickness of the layered structure may add up to 0.1 mm to 5.0 mm. As an example, it may be possible that an individual amorphous sheet having 0.5 mm thickness or amorphous alloy foils having 0.1 mm thickness when added in plurality of layers to form support structure may be challenging to roll. Therefore, the thickness of the individual layer may be chosen such that the individual layer thickness is in between 0.01 to 0.1 mm forming a combined flexible support structure thickness in the range of 0.01 mm to 5.0 mm. In an embodiment, there may be other materials between the layers of the plurality of layers that may be affecting the overall thickness/combined thickness or dimensions of the support structure. In an embodiment, the thickness of the individual layer may be chosen such that the individual layer thickness is in between 0.01 to 0.2 mm forming a combined flexible support structure thickness in the range of 0.02 mm to 5.0 mm. In an embodiment, the flexible support structure has at least two layers.

In an embodiment, it is a flexible display with layered spring structure using amorphous alloys capable of connecting to multiple devices.

The strain on the outer surface of the flat spring is linear to the thickness of the sheet. FIG. 2 shows a single spring's strain on the inner and outer surface according to an embodiment. As shown by FIG. 2, a single spring's strain is the difference between the length of the inner circle and the outer circle.

$$Length of 1 / 2 Circle ( Perimeter of semi - circle ) = Radius * π .$$

The thickness of the spring becomes the key determining factor. As the elastic limit of most amorphous alloys may be around 2%, the formula given below herein applies:

$$Height of the Spring ( t ) \leq radius * 0.02$$

where ‘t’ represents the thickness of the spring as the inner surface is in compressions and outer surface is in tension, acts as the fulcrum and is in linear and direct proportion to the amount of stress applied to the outer surface as the spring bends around a radius. Therefore, it can be derived that a thickness of Spring (flat sheet/ribbon) when less than 2% of the desired bend radius, will maintain the strain in the outer layer within 2% elastic strain limit. Given the above relation, a thickness can be derived if the desired strain limit is other than 2% or a bend radius for a given thickness to limit the elastic strain limit within a certain desired percent.

A spring is a slender, flat, and flexible strip of material that can bend or flex under load.

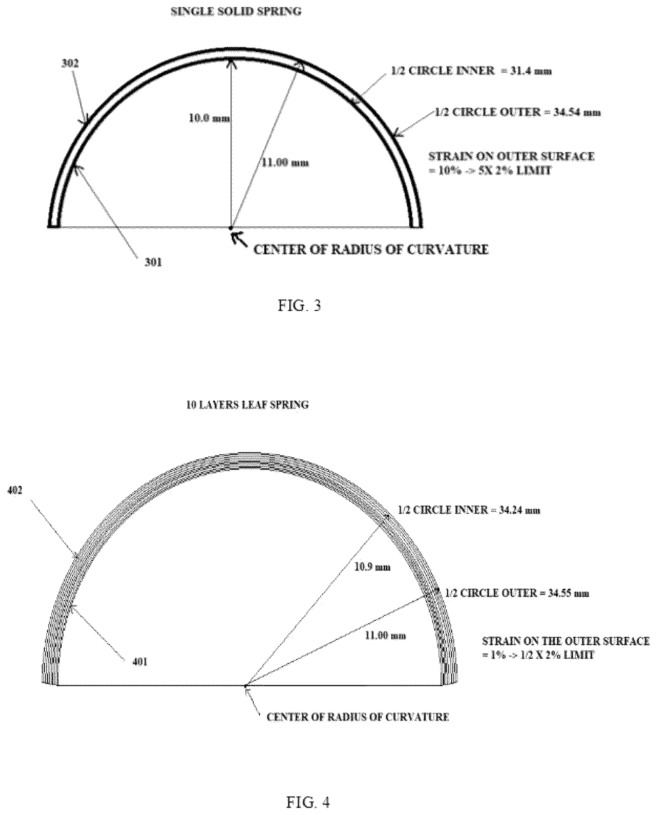

FIG. 3 shows a single solid spring and a strain on the inner and outer surface according to an embodiment. Consider a solid spring of thickness 1.00 mm bent to 10 mm radius. The inner most layer 301 will have 10 mm bend radius while the outer most layer 302 will have 11 mm bend radius. Outer most layer 302 will undergo maximum strain. Therefore, the inner surface 301 perimeter would be 10π, which is equal to 31.41 mm and the outer surface 302 perimeter would be 11π, which is equal to 34.55 mm.

The strain in the outer

$$surface = \frac{change in the length}{original length} \times 100 = \frac{( 34.55 - 31.41 )}{31.41} \times 100 ∼ 10 \% ;$$

which is 5× 2% strain limit. 2% strain limit which is generally the elastic strain limit of most materials. The elastic limit is the maximum stress a material can endure without sustaining permanent deformation. It is the point on a stress-strain curve beyond which the material cannot return to its original shape when the stress is removed. For example, if a material has an elastic limit of 0.2% strain or clastic strain limit of 0.2%, it means that it can undergo deformation up to 0.2% of its original length or dimension and still return to its original shape and size when the applied stress is removed. In other words, if a material has an elastic limit of 0.2% strain, and it has an original length of 100 millimeters, it can undergo a deformation of 0.2 millimeters before plastic deformation starts.

As an example, Stainless steel has elastic strain limit as 0.2-0.4% strain; thin metal foils of Copper and Aluminum may have elastic strain limit in the range of 1-3% strain. Plastic OLED substrates may have elastic strain limit up to 3% strain; Polyethylene Terephthalate (PET) may have an elastic strain limit about 1-2% strain; Organic Light-Emitting Diodes (OLEDs) displays integrated into flexible substrates may have elastic strain limit around 1%.

FIG. 4 shows a layered spring and a strain on the inner and outer surface according to an embodiment. Consider a layered spring, having 10 layers each 0.1 mm thick, and a total thickness of 1.00 mm, bent to 10 mm radius. The inner most surface of the inner most layer 401 will be having 10 mm bend radius while the outer most surface of the outer most layer 402 will have 11 mm bend radius. For the outer most layer 402, inner surface perimeter would be 10.9π, which is equal to 34.24 mm and the outer surface perimeter would be 11π, which is equal to 34.55 mm.

The strain in the outer surface of the outer most layer

$$402 = \frac{change in the length}{original length} \times 100 = \frac{( 34.55 - 34.24 )}{34.24} \times 100 ∼ 1 \% ;$$

which is

$$\frac{1}{2} \times 2 \%$$

strain limit. 2% strain limit which is generally the elastic strain limit of most materials.

Therefore, a layered structure when compared with a single solid structure has an advantage in terms of limiting the strain on the surfaces which undergo tight bend radius. Therefore, the materials, Stainless steel having clastic strain limit as 0.2-0.4% strain; thin metal foils of Copper and Aluminum having elastic strain limit in the range of 1-3% strain; Plastic OLED substrates having clastic strain limit up to 3% strain; Polyethylene Terephthalate (PET) having an elastic strain limit about 1-2% strain; Organic Light-Emitting Diodes (OLEDs) displays integrated into flexible substrates having clastic strain limit around 1% may function sufficiently when incorporated into a layered structure. Further, as can be seen from the calculations presented herein, material choice may depend on the bend radius and the thickness of the layer that is being chosen (based on number of layers chosen to provide the overall thickness) for the support structure.

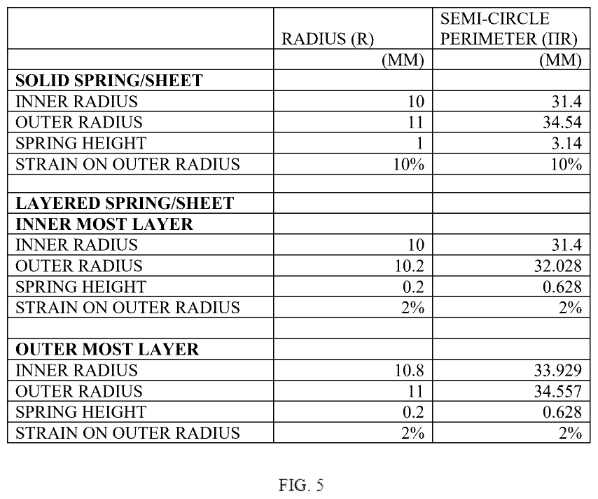

FIG. 5 shows a table comparing the strain in a solid spring and a layered spring according to an embodiment. Calculation of strain on a flat spring which is a solid flat spring having 1 mm thickness bent to 10 mm radius versus a layered spring where the layered spring has 5 layers, each layer having a thickness of 0.2 mm, is shown in FIG. 5. As explained herein and as shown in the calculations of the table presented in FIG. 5, the strain in the outer most layer is minimized in the layered spring versus the solid spring having no layers.

Solution defined: By stacking multiple layers of amorphous sheets that are free to slide against each other, The ‘r’ value can be reduced while structural integrity and durability arc maintained.

Thickness of the amorphous spring vs. Radius of the flexible display: Thickness of Spring is less than 2% of the desired radius. The thickness of spring when less than 2% of the desired bend radius will maintain the strain in the outer layer withing 2% elastic strain limit. For example, if the desired radius is 5.0 mm, then the thickness of the amorphous plate needs to be less than 0.1 mm thick. An amorphous spring of this thickness does not have sufficient strength to provide desired structural stability as well as the strength to spring back to a consistent flat position. If the thickness of the spring is increased to overcome these weaknesses, the spring is likely to experience breakage before the desired timeline.

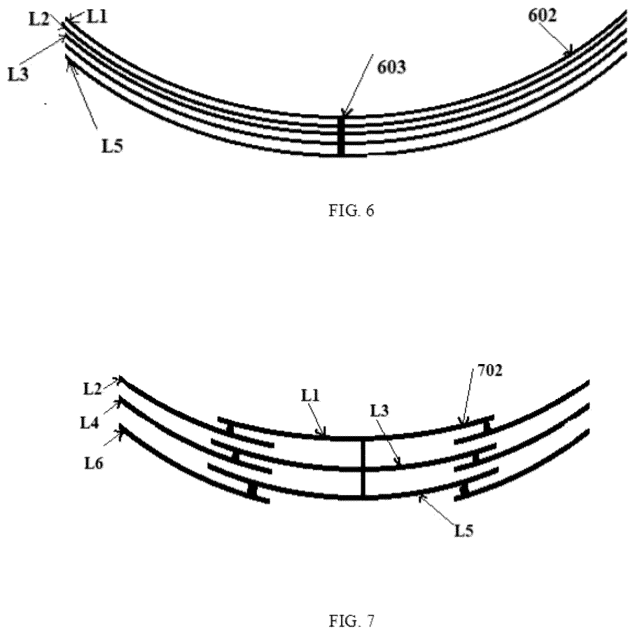

One method to accomplish both thickness of spring 0.1 mm and structural stability and flexibility, is to utilize thin sheets and layer them within a total thickness less than or equal to 0.1 mm, while allowing those layers, surfaces, to slide against each other. The layers provide strength and rigidity of the combined height of the entire layers, but the resulting strain on the outer surface is reduced in direct ratio to the number of layers used. The fulcrum, that determines the strain on the outer surface, begins at the inner surface of each layer. Thin sheets may be of amorphous material. FIG. 6 shows a first example for a layered pattern for the supporting structure of the display apparatus according to an embodiment. Multiple layers are joined at the flex line where the display would be bent, and the rest of the surface of the layers are allowed to move (i.e., glide) freely when the display is folded or rolled. The top layer 602 is towards the display side of the device and is the inner layer.

FIG. 7 shows a second example for a layered pattern for the supporting structure/display apparatus according to an embodiment. Another method to accomplish a layered display apparatus support structure is to join the plurality of layers at predetermined points. These points may be as shown in FIG. 7 which would limit the stress and thus the strain on the outmost surface when bent. Other configurations of joining the plurality of layers are contemplated with the requirement that the plurality of layers form enough support structure for the display and yet each layer would be free to glide on the other surfaces while being joined at predefined places. The top layer 702 is towards the display side of the device and is the inner layer.

Joining at predetermined positions is advantageous because it provides a simple and robust connection that can accommodate movement and reduce stress. Predetermined means the locations or points, at which the layers are joined or connected, have been intentionally chosen or specified in advance. These locations are not random but are carefully selected and designed to enable controlled and planned movement between the layers. These connection points are determined based on the desired functionality and intended movements of the structure. By connecting the layers at the predetermined points, the layers can glide or move freely over each other in a controlled and predictable manner. As shown in FIG. 6, the connection may be along the flex line, at the center of the strips 603, rigidly connecting all the layers, for example, layers L1, L2 . . . L5, and letting the rest of the unconnected areas to glide freely relative to the adjacent layers. L1 may be the layer closest to the display. In an embodiment, the layers can be arranged as shown in FIG. 7. The layers can be formed from a plurality of strips in each layer, for example, layer L2 is formed from two individual strips. Layer L1 is connected to L2 and L3, L2 is connected to L1, and L3 is connected to LA and L5 (L4 is connected to L3) and so forth. The arrangement of layers as shown in FIGS. 6 and 7 is an example, and many such forms may be designed with the requirement that the layers have to glide over each other, cover the given area, provide enough support, and the clastic strain limit in the layers is within 1.5% to 2%. In an embodiment, there may be places where support points may be provided between the layers, but these support points do not connect two layers rigidly. They may be connected to one layer and rest on the other layer providing support yet letting the layers glide over each other. According to an embodiment, the connection may be a point or spot connection or a continuous connection along a line where two surfaces or layers being connected. Each layer L1, L2 . . . etc., has an individual thickness and the flexible display support structure or apparatus has an overall or combined thickness. In an embodiment, the combined thickness may or may not be equal to the sum of individual layers as there may be other materials between the layers that affect the combined dimensions. Other materials could be electronic components, lubrication material, etc.

A layered spring should be composed of individual layers, each capable of bending independently and sliding or rolling along the adjacent layer's surface around either a bending axis or a rolling axis. If we have a layered spring where all the layers have interconnected surfaces that behave like a single, solid spring or a solid flat sheet when bent, it should not be classified as a true layered spring.

According to an embodiment it is a flexible display apparatus comprising a plurality of layers wherein each layer is connected to at least one other layer at a predetermined position, forming a connection, wherein the flexible display apparatus is part of a display of an electronic device, and wherein each layer of the plurality of layers comprises a rotational degree of freedom and glides relative to an adjacent layer of the plurality of layers about an axis of fold or roll, when the display is folded or rolled.

According to an embodiment of the flexible display apparatus, each layer of the plurality of layers comprises a material having an elastic strain limit of at least 1.5%. According to an embodiment of the flexible display apparatus, a flexible silica glass surface forms a first surface layer towards a display side and is supported by a second surface layer with an amorphous sheet. According to an embodiment of the flexible display apparatus, a flexible silica glass surface forms a first surface layer towards a display side and is supported by a second surface layer with a material having an elastic limit of at least 1%. According to an embodiment of the flexible display apparatus, each layer of the plurality of layers comprises a material having an elastic limit of at least 1%.

According to an embodiment of the flexible display apparatus, the amorphous sheet comprises either silica or alloys. According to an embodiment of the flexible display apparatus, an Organic Light-Emitting Diode (OLED) is printed on the flexible silica glass surface.

According to an embodiment of the flexible display apparatus, the flexible silica glass surface is firmly bonded to one or more layers of amorphous alloy along a flex zone. According to an embodiment of the flexible display apparatus, the flexible silica glass surface is firmly bonded to one or more layers of silica along a flex zone.

According to an embodiment of the flexible display apparatus, at least a layer of the plurality of layers comprises an amorphous material. According to an embodiment of the flexible display apparatus, the amorphous material comprises iron-based amorphous ribbons. According to an embodiment of the flexible display apparatus, the amorphous material comprises silica-based glass sheets. According to an embodiment of the flexible display apparatus, the plurality of layers of the flexible display apparatus forms a spring structure.

According to an embodiment of the flexible display apparatus, a magnetic field is used to hold the plurality of layers in stable position, until a sufficient force is applied to free the layers.

According to an embodiment of the flexible display apparatus, the connection is a rigid connection. According to an embodiment of the flexible display apparatus, the connection comprises a mechanical joint comprising one of a spot welding, a fastening joint, and a rivet. According to an embodiment of the flexible display apparatus, the connection comprises a mechanical joint comprising a telescopic sliding joint.

According to an embodiment of the flexible display apparatus, the predetermined position is configured such that varying the predetermined position varies a degree of free gliding. The Predetermined position is the location where the two layers are joined. It can be based on the rigidity and freedom of glide as required. According to an embodiment of the flexible display apparatus, the display comprises at least one organic light emitting diode; wherein at least one of the plurality of the plurality of layers comprises at least one amorphous alloy; and wherein the display remains at least substantially flat after folding and unfolding multiple times.

According to an embodiment of the flexible display apparatus, the flexible display apparatus is part of one or more of a mobile phone, a smart phone, a personal digital assistant device, a computer, a television, a wall-mountable display. According to an embodiment of the flexible display apparatus, each layer of the plurality of layers has a different thickness. According to an embodiment of the flexible display apparatus, each layer of the plurality of layers has the same thickness. According to an embodiment of the flexible display apparatus, a first layer of the plurality of layers closest to a display side has a first thickness different from a second layer of the plurality of layers farther from the display side having second thickness, wherein the first thickness is smaller than the second thickness, and wherein an elastic limit of a first material of the first layer and a second material of the second layer is at least 1.5% strain.

According to an embodiment of the flexible display apparatus, a lubrication mechanism is positioned between adjacent layers, said lubrication mechanism is configured to reduce friction and promote a free movement of said layers relative to each other. According to an embodiment of the flexible display apparatus, the lubrication mechanism comprises a dry lubricant. According to an embodiment of the flexible display apparatus, the lubrication mechanism comprises a liquid lubricant contained within sealed channels between adjacent layers.

In an embodiment, it is a flexible display with layered spring. In an embodiment, it is a structure using amorphous alloys capable of connecting to multiple devices. In an embodiment, amorphous sheets can be fixed in various points to reinforce the areas as needed while allowing the layers to move freely to form the layered structure to be utilized in displays.

In an embodiment, the layered structure forms the hinge portion of the support structure. The hinge portion of a flexible display refers to a specific region or component within a device that allows for the flexing, bending, or folding of the display screen.

Variable thickness and geometry of the amorphous layers: The inner layer that bends around the smallest radius may be thinner. The subsequent supporting layers may increase in thickness as long as the 2% strain rule is followed. This may help to increase structural stability while maintaining desired durability. It is contemplated that other materials may also be used as long as the relationship between bend radius and thickness of the spring, sheet, yield the elastic strain limit as per the materials property. The other way of working with the chosen material is to derive the thickness given the material property and the bend radius.

Flexible Silica Glass marketed by Corning® (Gorilla® Glass) can be layered to provide the same benefits as Amorphous Alloy sheets. However, Silica Glass cannot match the ultimate strength of amorphous alloys for specific volume. Since tightness of the roll radius is a critical factor, a Layered Spring Structure made of Silica Glass might be limited to roll up displays with relatively bigger diameters.

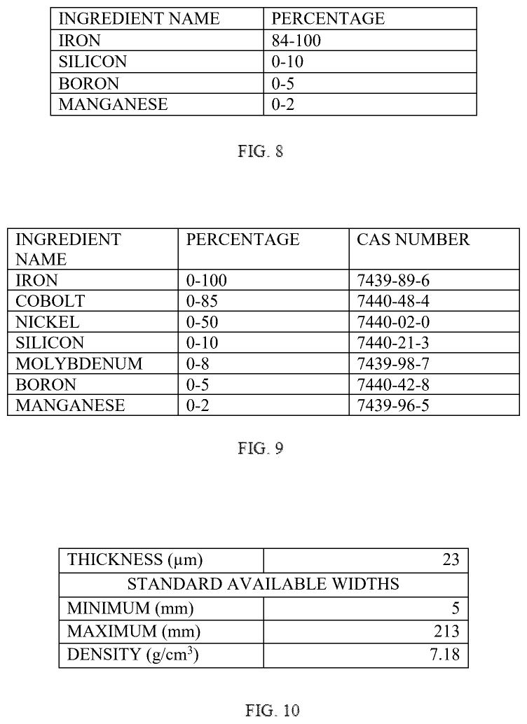

FIG. 8 shows a first example for chemistry for Iron (Fe) based amorphous Ribbons according to an embodiment. In an embodiment, the Iron based amorphous ribbons may be utilized for the layers of the display structure. The chemistry of the iron-based amorphous ribbons is provided in FIG. 8.

FIG. 9 shows a second example for chemistry for Iron (Fe) based amorphous Ribbons according to an embodiment. In an embodiment, Iron-based amorphous ribbons, with chemistry/composition different from the one shown in FIG. 8, may be utilized for the layers of the display structure. The chemistry of the iron-based amorphous ribbons may be as shown in FIG. 9.

According to an embodiment of the flexible display apparatus, the iron based amorphous ribbons comprise iron in a first range of 84-100%, silicon in a second range of 0-10%, boron in a third range of 0-5%, and manganese in a fourth range of 0-2%.

According to an embodiment of the flexible display apparatus, the iron based amorphous ribbons comprise iron in a first range of 0-100%, cobalt in a second a second range of 0-85%, Nickel in a third range of 0-50%, silicon in a fourth range of 0-10%, molybdenum in a fifth range of 0-8%, boron in a sixth range of 0-5%, and manganese in a seventh range of 0-2%.

FIG. 10 shows dimensions of Iron (Fc) based amorphous Ribbons that are available in the market readily according to an embodiment. Amorphous ribbons that are available in the market may be used to form the display apparatus structure. The thickness may be in the range of/about 23 micrometers. In an embodiment, the thickness may be in the range of 0.1 micrometers to 1 milli meter (mm). In an embodiment, the lower limit of the thickness may be in the range of 0.1 micrometers to 0.5 mm. In an embodiment, the upper limit of the thickness may be in the range of 0.3 micrometers to 0.5 mm.

In an embodiment, the width of the ribbon may be in the range of 5 mm to 213 mm. In an embodiment, the width of the ribbon may be in the range of 1 mm to 200 mm. In an embodiment the ribbon width may be in the range of 10 mm to 250 mm. In an embodiment, the width of the ribbon chosen may be based on the display size of the electronic device on which the layered structure of the display is utilized. For example, the width is chosen such that it may be of the size of display of the electronic device, or half the size of display of the electronic device, or ⅓ the size of display of the electronic device, or in any desired width such that the display of the electronic device has structural integrity and high flexibility and is supported in full.

In an embodiment, the layers may be comprising silica based glass sheets.

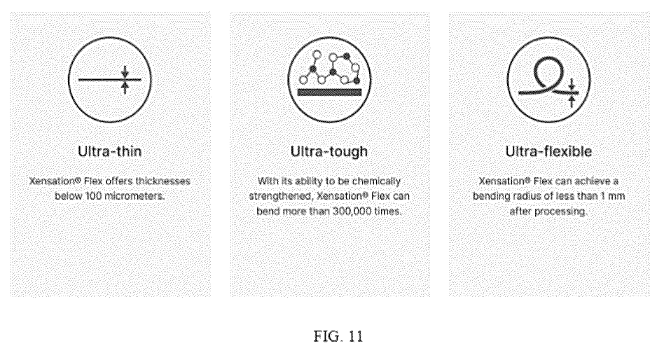

FIG. 11 shows properties of Silica glass by Schott® according to an embodiment. The Xensation® Flex offers thickness below 100 micrometers with a bend radius of less than 1 mm and the ability to bend more than 300,000 times. Thus, commercially available materials may be utilized to form the layers.

Several materials may be used for substrates or backplanes in flexible displays, including thin glass substrates like Corning's Willow Glass or Schott's Xensation®, which are specially designed to be both flexible and rigid. Plastic materials like Polyethylene Terephthalate (PET) and Polyimide (PI) are also commonly used for their flexibility and high-temperature resistance. Thin metal foils, such as aluminum or copper, offer excellent rigidity while being lightweight. In some cases, organic materials or hybrid substrates combining various materials may be employed, with the material choice depending on factors like display size, shape, durability, and cost. The selection of the substrate material is an important consideration in flexible display design and manufacturing.

In an embodiment, the layers of the plurality of layers may be made of the same material or of different materials. In an embodiment the layers may be made of similar thicknesses and of different thicknesses for each layer. In an embodiment, each layer of the plurality of layers may be made of the same thickness and the same material. In an embodiment, each layer of the plurality of layers may be made of different thicknesses and of different materials. In another embodiment, the thickness and material may be the same for a group of layers from the plurality of layers.

In an embodiment, the top layer, on which OLED is printed for display, may be comprised of flexible silica glass and is firmly bonded to one or more layers of amorphous alloy or silica support along the flex zone.

Iron (Fe) based amorphous ribbons and silica based glass sheets may be used to form the layers. Fe based amorphous metallic ribbons that Metglas® produces are commercially available in the market and may be chosen for support structures. A Flexible silica glass (Gorilla Glass®) sheet may also be used; and beyond just the surface of a flexible display, as a flexible support structure.

Flexible Display as all-In-One Display and Input Device

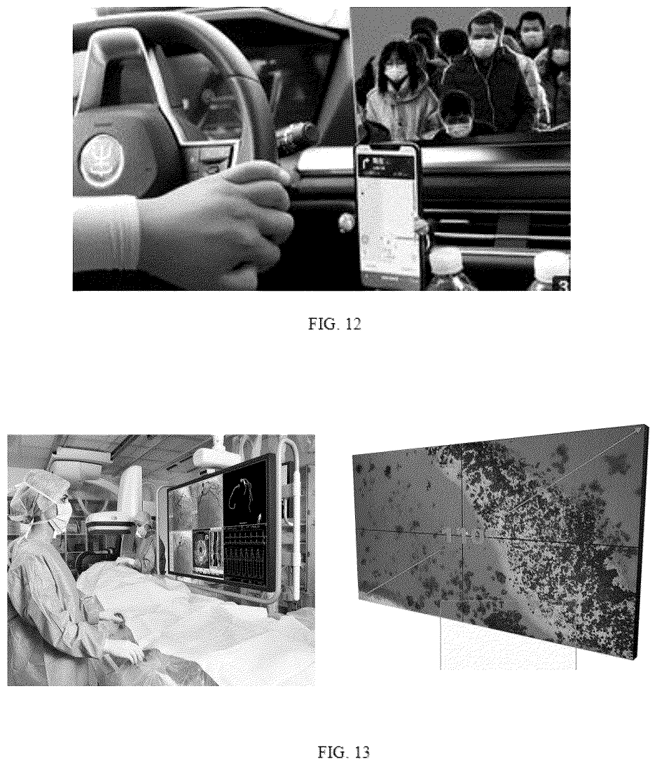

1) Foldable Displays (FDs) that can connect to existing smartphones and other smart devices mainly function as input and display devices. FIG. 12 shows a roll up/foldable screen that can be used as an extension to the existing smart phone screen according to an embodiment.

The key advantage of such a simple display/input device that leverages the existing smartphones and computers is that a FD leverages the existing devices. Most smartphones would function instantly as a flexible display device at about ⅓ the cost of purchasing a new smart phone with FD.

Both the folding and roll-up displays can connect to multiple Central Processing Units (CPUs), Smart Phones, or Printers, Audio Video devices, and TV remotes to function as the universal input output device that connects us to our electronics world.

For example, a pen sized roll-up display can unfold to a Mini Pad sized display and connect to home or office laptops, computers, cell phones, vehicles, and auto security.

Medical staffs can leverage the high-definition display to show MRI and other medical information to patients. FIG. 13 shows a roll up/foldable screen that can be used as an extension to the existing screen according to an embodiment.

A Flexible display connected to a smart phone can conduct Zoom meetings as well as personal communications.

If the main display in an automobile is used for the GPS map function, your ability to control many other functions in the car simultaneously may be limited. Thus, you can assign the FD as the display for the GPS while leaving the main auto display for other functions.

2) FDs that function as smartphones or laptops need little explanation. However, even a fully independent smartphone with FD can function in an integrated manner to either control and/or simply to display information.

3). Two or more flexible displays can be connected to form a single continuous screen.

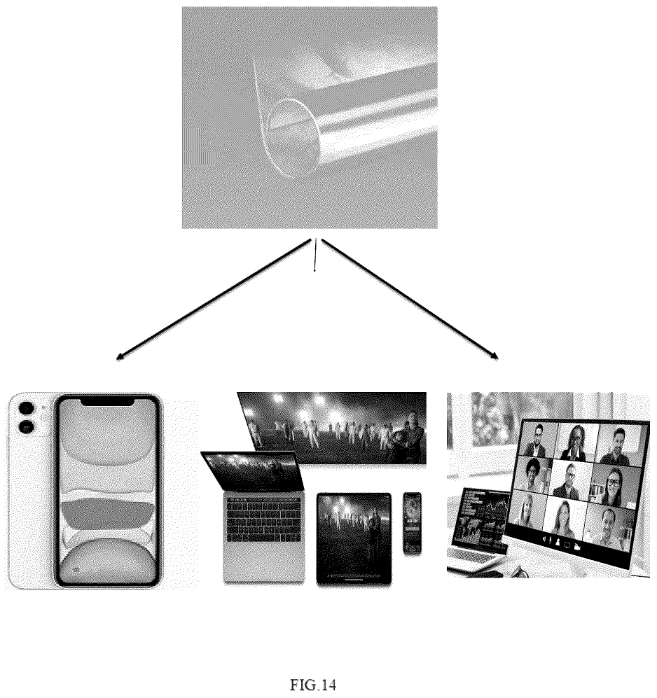

The display can function unattached, independent of the CPU via Bluetooth® and can be charged using wireless charging. FIG. 14. shows a roll up/foldable screen that can be used as an extension in various scenarios and for applications according to an embodiment.

The flexible display (i) can connect Cell Phones, (ii) can be used for Multiple Screens as One Unit and (iii) can be used as Secondary Displays.

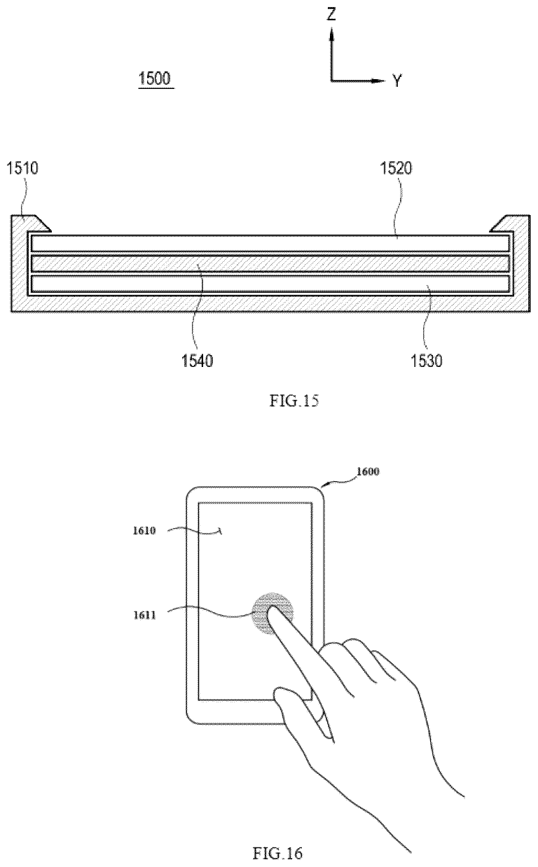

FIG. 15 shows a lateral cross-section view schematically illustrating the internal structure of the display apparatus according to an exemplary embodiment. As shown in FIG. 15, the display apparatus 1500, according to an embodiment, may include a housing 1510, a display panel 1520, an image processing board 1530, and a panel support member 1540 interposed between the display panel 1520 and the image processing board 1530. The housing 1510, the display panel 1520 and the image processing board 1530 are made bendable by having a flexible structure. The panel support member 1540 is placed behind or beneath the display panel 1520 and supports the display panel 1520. When a user touches the upper surface of the display panel 1520 in front of or on the display panel 1520, the panel support member 1540 prevents a touched area of the display panel 1520 from being recessed in the −Z direction. Further, the panel support member 1540 has the flexible structure so that the display apparatus 1500 can be bent in the Z direction, or the −Z direction. FIG. 6 and FIG. 7 as described herein provide the detailed panel support member 1540.

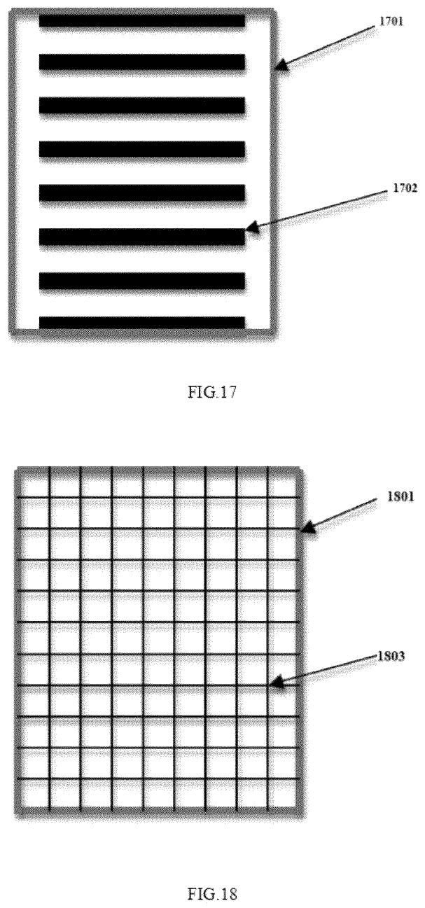

FIG. 16 illustrates that a display panel touched in the display apparatus has a flexible structure, according to an embodiment. As shown in FIG. 16, the display apparatus 1600, according to an embodiment, is achieved by a mobile apparatus in which a touch screen is applied to a display panel 1610. When a user touches a surface of the display panel 1610, interaction with the display apparatus 1600 is performed. To make the display apparatus 1600 have the flexible structure according to the foregoing exemplary embodiments, elements, which constitute the display apparatus 1600, are also required to have the flexible structure. If a user touches the display panel 1610 for operations, the touched area 1611 is pressed and recessed inward, and an image in the corresponding area 1611 is contorted and distorted. To prevent this, a structure for supporting the back of the display panel 1610 is applied to the display apparatus 1600.

According to an embodiment, it is a display comprising a flexible display apparatus, wherein the flexible display apparatus comprises a plurality of layers wherein each layer is connected to at least one other layer at a predetermined position forming a connection, and wherein each layer of the plurality of layers comprises a rotational degree of freedom and glides relative to an adjacent layer of the plurality of layers about an axis of fold or roll when the display is folded or rolled.

According to an embodiment of the display, the display is operable to be a secondary display to an electronic device. According to an embodiment of the display, the display is operable to be an extension of an existing display to an electronic device. According to an embodiment of the display, the display is operable to be interconnected with a second display of similar nature to form a continuous display.

According to an embodiment of the display, the display is operable to be connected via a wireless connection or a wired connection.

According to an embodiment of the display, the display is operable for wireless charging. According to an embodiment of the display, the display is a touch sensitive display.

Amorphous Alloys: An alloy may refer to a solid solution of two or more metal elements (e.g., at least 2, 3, 4, 5, or more elements) or an intermetallic compound (including at least one metal element and at least one non-metal element). The term “element” herein may refer to an element that may be found in the Periodic Table. A metal may refer to any alkali metals, alkaline earth metals, transition metals, post-transition metals, lanthanides, actinides, and metalloids.

An amorphous alloy may refer to an alloy having an amorphous, non-crystalline atomic or microstructure. The amorphous structure may refer to a glassy structure with no observable long range order; in some instances, an amorphous structure may exhibit some short range order. Thus, an amorphous alloy may sometimes be referred to as a “metallic glass.” An amorphous alloy may refer to an alloy that is at least partially amorphous, including at least substantially amorphous, such as entirely amorphous, depending on the context. In one embodiment, an amorphous alloy may be an alloy of which at least about 50% is an amorphous phase—e.g., at least about 60%, about 70%, about 80%, about 90%, about 95%, about 99% or more. The percentage herein may refer to volume percent or weight percent, depending on the context. The term “phase” herein may refer to a physically distinctive form of a substance, such as microstructure. For example, a solid and a liquid are different phases. Similarly, an amorphous phase is different from a crystalline phase.

Amorphous alloys may contain a variety of metal elements and/or non-metal elements. In some embodiments, the amorphous alloys may comprise zirconium, titanium, iron, copper, nickel, gold, platinum, palladium, aluminum, or combinations thereof. In some embodiments, the amorphous alloys may be zirconium-based, titanium-based, iron-based, copper-based, nickel-based, gold-based, platinum-based, palladium-based, or aluminum-based. The term “M-based” when referred to an alloy may refer to an alloy comprising at least about 30% of the M element—e.g., about 40%, about 50%, about 60%, about 70%, about 80%, about 90%, about 95%, or more. The percentage herein may refer to volume percent or weight percent, depending on the context.

An amorphous alloy may be a bulk solidifying amorphous alloy. A bulk solidifying amorphous alloy, or bulk amorphous alloy, or bulk metallic glass (“BMG”), may refer to an amorphous alloy that has at least one dimension in the millimeter range, which is substantially thicker than conventional amorphous alloys, which generally have a thickness of 0.02 mm. In one embodiment, this dimension may refer to the smallest dimension. Depending on the geometry, the dimension may refer to thickness, height, length, width, radius, and the like. In some embodiments, this smallest dimension may be at least about 0.5 mm—e.g., about 1 mm, about 2 mm, about 3 mm, about 4 mm, about 5 mm, about 6 mm, about 8 mm, about 10 mm, about 12 mm, or more. The magnitude of the largest dimension is not limited and may be in the millimeter range, centimeter range, or even meter range.

An amorphous alloy, including a bulk amorphous alloy, described herein may have a critical cooling rate of about 500 K/sec or less, in contrast to that of 105 K/sec or more for conventional amorphous alloys. The term “critical cooling rate” herein may refer to the cooling rate below which an amorphous structure is not energetically favorable and thus is not likely to form during a fabrication process. In some embodiments, the critical cooling rate of the amorphous alloy described herein may be, for example, about 400 K/sec or less—e.g., about 300 K/sec or less, about 250 K/sec or less, about 200 K/sec or less. Some examples of bulk solidifying amorphous alloys may be found in U.S. Pat. Nos. 5,288,344; 5,368,659; 5,618,359; and 5,735,975. In some embodiments wherein the desired diameter (or width, thickness, etc., depending on the geometry) is small, a higher cooler rate, such as one used in the conventional amorphous alloy fabrication process, may be used.

The amorphous alloy may have a variety of chemical compositions. In one embodiment, the amorphous alloy is a Zr-based alloy, such as a Zr—Ti based alloy, such as (Zr, Ti)ₐ(Ni, Cu, Fe)_{b}(Be, Al, Si, B)_{c}, where each of a, b, c, is independently a number representing atomic % and a is in the range of from 30 to 75, b is in the range of from 5 to 60, and c is in the range of from 0 to 50. Other incidental, inevitable minute amounts of impurities may also be present. In some embodiments, these alloys may accommodate substantial amounts of other transition metals, such as Nb, Cr, V, Co. A “substantial amount” in one embodiment may refer to about 5 atomic % or more—e.g., 10 atomic %, 20 atomic %, 30 atomic %, or more.

In one embodiment, an amorphous alloy herein may have the chemical formula (Zr, Ti)_{b}(Ni, Cu)_{b}(Be)_{c}, where each of a, b, c, is independently a number representing atomic % and a is in the range of from 40 to 75, b is in the range of from 5 to 50, and c is in the range of from 5 to 50. Other incidental, inevitable minute amounts of impurities may also be present. In another embodiment, the alloy may have a composition (Zr, Ti)_{b}(Ni, Cu)_{b}(Be)_{c}, where each of a, b, c, is independently a number representing atomic % and a is in the range of from 45 to 65, b is in the range of from 7.5 to 35, and c is in the range of from 10 to 37.5 in atomic percentages.

In another embodiment, the amorphous alloy described herein may have the chemical formula (Zr)ₐ(Nb, Ti)_{b}(Ni, Cu)_{c}((Al)_{d}, where each of a, b, c, d is independently a number representing atomic % and a is in the range of from 45 to 65, b is in the range of from 0 to 10, c is in the range of from 20 to 40, and d is in the range of from 7.5 to 15. Other incidental, inevitable minute amounts of impurities may also be present.

In some embodiments, the amorphous alloy may be a ferrous metal based alloy, such as a (Fc, Ni, Co) based compositions. Examples of such compositions are disclosed in U.S. Pat. No. 6,325,868 and in publications (A. Inoue et. al., Appl. Phys. Lett., Volume 71, p 464 (1997)), (Shen et. al., Mater. Trans., JIM, Volume 42, p 2136 (2001)), and Japanese patent application 2000126277 (Pub. #2001303218 A). For example, the alloy may be Fe₇₂A₁₅Ga₂P₁₁C₆B₄, or FC₇₂Al₇Zr₁₀Mo₅W₂B₁₅.

Amorphous alloys, including bulk solidifying amorphous alloys, may have high strength and high hardness. The strength may refer to tensile or compressive strength, depending on the context. For example, Zr and Ti-based amorphous alloys may have tensile yield strengths of about 250 ksi or higher, hardness values of about 450 Vickers or higher, or both. In some embodiments, the tensile yield strength may be about 300 ksi or higher—e.g., at least about 400 ksi, about 500 ksi, about 600 ksi, about 800 ksi, or higher. In some embodiments, the hardness value may be at least about 500 Vickers—e.g., at least about 550, about 600, about 700, about 800, about 900 Vickers, or higher.

In one embodiment, ferrous metal based amorphous alloys, including the ferrous metal based bulk solidifying amorphous alloys, can have tensile yield strengths of about 500 ksi or higher and hardness values of about 1000 Vickers or higher. In some embodiments, the tensile yield strength may be about 550 ksi or higher—e.g., at least about 600 ksi, about 700 ksi, about 800 ksi, about 900 ksi, or higher. In some embodiments, the hardness value may be at least about 1000 Vickers—e.g., at least about 1100 Vickers, about 1200 Vickers, about 1400 Vickers, about 1500 Vickers, about 1600 Vickers, or higher.

As such, any of the afore-described amorphous alloys may have a desirable strength-to-weight ratio. Furthermore, amorphous alloys, particularly the Zr- or Ti-based alloys, may exhibit good corrosion resistance and environmental durability. The corrosion herein may refer to chemical corrosion, stress corrosion, or a combination thereof.

The amorphous alloys, including bulk amorphous alloys, described herein may have a high clastic strain limit of at least about 0.5%, including at least about 1%, about 1.2%, about 1.5%, about 1.6%, about 1.8%, about 2%, or more—this value is much higher than any other metal alloy known to date. In an embodiment, at least a layer may comprise of amorphous alloy.

In some embodiments, the amorphous alloys, including bulk amorphous alloys, may additionally include some crystalline materials, such as crystalline alloys. The crystalline material may have the same or different chemistry from the amorphous alloy. For example, in the case wherein the crystalline alloy and the amorphous alloy have the same chemical composition, they may differ from each other only with respect to the microstructure.

In some embodiments, crystalline precipitates in amorphous alloys may have an undesirable effect on the properties of amorphous alloys, especially on the toughness and strength of these alloys, and as such it is generally preferred to minimize the volume fraction of these precipitates. However, there may be cases in which ductile crystalline phases precipitate in-situ during the processing of amorphous alloys, which may be beneficial to the properties of amorphous alloys, especially to the toughness and ductility of the alloys. One exemplary case is disclosed in C. C. Hays et. al, Physical Review Letters, Vol. 84, p 2901, 2000. In at least one embodiment herein, the crystalline precipitates may comprise a metal or an alloy, wherein the alloy may have a composition that is the same as the composition of the amorphous alloy or a composition that is different from the composition of the amorphous alloy. Such amorphous alloys comprising these beneficial crystalline precipitates may be employed in at least one embodiment described herein.

A particular advantage of bulk solidifying amorphous alloys is their stability in the supercooled liquid region, defined as the viscous liquid regime above the glass transition temperature in one embodiment. The stability of this viscous liquid regime may be generally measured with ΔT, which in one embodiment herein refers to the difference between the onset of crystallization temperature, Tx, and the onset of glass transition temperature, Tg, as determined from standard Differential Scanning calorimetry (“DSC”) measurements at conventional heating rates (e.g. 20° C./min). In some embodiments, the bulk solidifying amorphous alloys may have ΔT of at least about 30° C.—e.g., at least about 50° C., about 60° C., about 70° C., about 80° C., about 90° C., or more.

According to an embodiment of the flexible display apparatus, the amorphous material comprises an amorphous alloy that has an elastic limit of at least 1.5% strain selected from (Zr,Ti)a(Ni,Cu,Fc)b(Bc,Al,Si,B)c wherein a=30-75; b=5-60 & c=0-50 atomic percentages; (Zr,Ti)a(Ni,Cu)b(Be)c wherein a=40-75; b=5-50; & c=5-50 in atomic percentages; (Zr,Ti)a(Ni,Cu)b(Be)c wherein a=40-65; b=7.5-35; & c=10-37.5 in atomic percentages; and (zr)a(Nb,Ti)b(Ni,Cu)c(Al)d wherein a=45-65; b=0-10; c=20-40; & d=7.5-15.

Though bulk solidifying amorphous chemistries are considered, in order to leverage multiple layers of thin amorphous sheets, Fe based ribbons and Silica based sheets may be considered to form the spring structure.

According to an embodiment of the flexible display apparatus, the amorphous alloy comprises a Zr-based, a Ti-based, a Zr—Ti-based, an Fe-based, or combinations thereof, amorphous alloy.

According to an embodiment of the flexible display apparatus, the amorphous alloy is at least substantially free of Be. According to an embodiment of the flexible display apparatus, the amorphous alloy further comprises a plurality of crystalline precipitates.

According to an embodiment of the flexible display apparatus, at least one of the plurality of layers comprises a plurality of structural components comprising wires, strips, fibers, ribbons, or combinations thereof, wherein the plurality of structural components is configured to provide structural stability and rigidity to maintain a flat shape of the display after multiple folding and unfolding or rolling and unrolling of the display. According to an embodiment of the flexible display apparatus, the plurality of the structural components comprises a series of horizontally aligned strips. According to an embodiment of the flexible display apparatus, the plurality of the structural components comprises a mesh of horizontally and longitudinally aligned fibers. According to an embodiment of the flexible display apparatus, at least one of the plurality of the structural components comprises (i) fibers having a diameter of between about 0.01 mm and about 0.5 mm, or (ii) ribbons having a thickness of between about 0.023 mm and a width of about 2 mm and about 213 mm.

Amorphous ribbons: Amorphous ribbons, also known as metallic glass ribbons or metallic glass foils, are unique materials with a non-crystalline, amorphous atomic structure. Amorphous ribbons are typically thin and flat, with widths ranging from a fraction of a millimeter (e.g., around 0.025 mm or 25 micrometers) to several millimeters. Their thickness can vary but is often in the range of tens to hundreds of micrometers. The length of amorphous ribbons can be quite long, often wound onto spools or rolls and can be cut to any desired length. Amorphous ribbons arc typically made from alloys of various metallic elements. Common elements used in the composition of metallic glasses include, transition metal elements like iron (Fc), nickel (Ni), and cobalt (Co) are often used as primary constituents, Metalloid elements like boron (B) and silicon (Si) are added to the alloy to disrupt the formation of a crystalline structure and promote the amorphous state, and small amounts of other elements, such as phosphorus (P), carbon (C), or chromium (Cr), may be included to fine-tune the properties of the alloy.

The specific composition of amorphous ribbons can vary depending on the desired properties and intended applications. Amorphous ribbons are produced through a rapid solidification process called melt spinning, where molten metal is rapidly quenched onto a rotating cooled wheel, preventing the formation of a crystalline structure. This rapid cooling results in the amorphous atomic arrangement characteristic of metallic glasses. The thin and flat shape of the ribbons makes them conducive to applications where a combination of unique properties, such as high strength, magnetic characteristics, or corrosion resistance, is needed.

Foldable Display Structure (FDS): One aspect of the embodiments described herein provides a foldable display structure (“FDS”) comprising amorphous alloys, and methods of making near-net shape foldable display structures from amorphous alloys. Due at least in part to the amorphous alloys, the FDS described herein may have characteristics that are both enabling and much improved over pre-existing display structures. The surprising advantages of foldable display structures comprising amorphous alloys, particularly bulk solidifying amorphous alloys, will be described in various embodiments below.

One embodiment provides FDS comprising amorphous alloys, the amorphous alloys providing form and shape durability combined with high flexibility, high resistance to chemical and environmental effects, and low-cost near-net shape fabrication for intricate design and shapes. Another embodiment provides a method of making foldable display structures from such amorphous alloys in near-net shape. The amorphous alloys may be bulk solidifying amorphous alloys.

Provided in one embodiment is a structure, the structure containing a display, and at least one structural component disposed over a portion of the display. The display may contain at least one organic material, including an OLED. In one embodiment, the display need not contain an organic material. In general, any flexible display material may be used. The display, or a portion thereof, may be foldable. In some embodiments, the entire structure is foldable. In one embodiment, the structure may be, or may comprise, a foldable display and, optionally, structural components. In one embodiment the structure comprises a display and at least one structural component.

At least one structural component may contain at least one amorphous alloy. In one embodiment, the at least one structural component comprises essentially of an amorphous alloy. In another embodiment, at least one structural component comprises of an amorphous alloy. The amorphous alloy may be any of the aforedescribed amorphous alloys, with any of the aforedescribed properties. In one embodiment, the amorphous alloy may be a bulk solidifying amorphous alloy.

The combination of high strength and high strength-to-weight ratio of the bulk solidifying amorphous alloys in one embodiment may significantly reduce the overall weight and bulkiness of foldable display structures, thereby allowing for the reduction of the thickness of these display structures while maintaining structural integrity and high flexibility. Furthermore, as described above, amorphous alloys, including bulk solidifying amorphous alloys, have high clastic strain limits. This property is important for the use and application of foldable display structures; specifically, a high clastic strain limit may allow the display structure to be thin and highly flexible. Additionally, a high elastic strain limit also may allow the foldable display structures described herein to sustain loading and/or flexing without permanent deformation or destruction and enable them to fold (and roll) into compact shapes for multiple use and opening and closure. The term “folding” herein may include “rolling” to refer to compacting a material. Due at least in part to the high elasticity, the foldable display described herein after multiple folding and unfolding of the structural component, may remain at least substantially flat, such as completely flat. In one embodiment, the foldable display may remain at least substantially at the same level of flatness after multiple folding and unfolding as before it was folded for the first time.

In addition, due at least in part to the amorphous alloy, the foldable display structures described herein may exhibit resistance to corrosion (e.g., chemical corrosion, stress corrosion, etc.) and high inertness. The high corrosion resistance and inertness of the amorphous alloy in the structural component may be useful for preventing foldable display structures from getting decayed due the environmental effects. Finally, the aforedescribed properties, in combination with the high strength, high hardness, high elasticity and corrosion resistance properties, may provide a foldable display structure that is durable and resistant to wear and scratch during normal use.

The foldable display structures, including the display and the structural component(s), described herein may have any geometry, including size or shape. The structure may have a symmetrical shape or an asymmetrical shape. In a plane view, the foldable display structures may be a square, rectangle, circle, elliptical, a polygon, or an irregular shape. In contrast to a frame or a housing, the structural component in many embodiments described herein does not cover an entire surface of the display. The structural component(s) may also have a variety of geometries, depending at least in part on the geometry of the foldable display. For example, the structural component may comprise wires, strips, fibers, ribbons, or combinations thereof. These wires, strips, fibers, ribbons, etc., may be disposed over (or directly on) the display in parallel to each other (or almost parallel to each other) or they may intersect one another to form a mesh. In one embodiment, the portion of the display that is foldable corresponds to the portion of the display over (or directly on) which the at least one structural component is disposed of. The structural component may be joined to the display by any technique. In one embodiment, the structural component is joined to the display by a polymer, such as an epoxy glue or any other material that may bond the structural component to the display.

The display structure described herein may have multiple layers. In one embodiment, the structural component comprising an amorphous alloy may be disposed over a substrate layer, which in turn may be disposed over the display. The structural component may be sandwiched between the display and the substrate or may be over (or directly on) the substrate that is over (or directly on) the display.

The structural components may have any suitable dimensions, depending on the application. FIG. 17 shows a schematic of an exemplary foldable display structure comprising a display 1701 and a structural component comprising a series of horizontally aligned strips 1702 comprising an amorphous alloy (e.g., amorphous alloy strips or ribbons). FIG. 6 and FIG. 7 as described herein provide the structure comprising multiple layers for each of horizontally aligned ribbons 1702. The strips may have a thickness of between about 1 μm and 2.0 mm—e.g., between about 0.001 mm and about 1.5 mm, between about 0.2 mm and about 1.0 mm, between about 0.4 mm and about 0.8 mm, between about 0.5 mm and about 0.6 mm. Other ranges are also possible. The strips may have a width of between about 0.5 and about 250.0 mm—e.g. between about 0.5 mm and about 15 mm, between about 2.0 mm and about 10 mm, between about 4.0 mm and about 8.0 mm, between about 5.0 mm and about 6.0 mm. Other ranges are also possible. The length of the strips may vary, depending at least in part on the geometry of the display over (or directly on) which the structural component is disposed of. The strips may be extended to the edge of the display or extended further outward of the edge of the display. In this embodiment, the display may be folded (including being rolled) in a segmented manner, with the strips providing certain rigidity along the display. In a preferred embodiment the strips are bonded to an OLED display with various joining methods such as using epoxy glue.

FIG. 18 shows a schematic of an exemplary foldable display structure comprising a display 1801 and a structural component comprising a mesh of horizontally and longitudinally aligned fibers 1803 comprising an amorphous alloy (e.g., amorphous alloy strips or ribbons). FIG. 6 and FIG. 7 as described herein provide the structure comprising multiple layers for each of horizontally and longitudinally aligned ribbons 1801 and 1803. The fibers may have a diameter of between about 0.01 mm and 2.0 mm—e.g., between about 0.02 mm and about 1.5 mm, between about 0.03 mm and about 1.0 mm, between about 0.05 mm and about 0.5 mm, between about 0.1 mm and about 0.4 mm, between about 0.2 mm and about 0.3 mm. Other ranges are also possible. The mesh network may be extended to the edge of the display or may be extended further outward of the edge of the display. In this embodiment, the display can be folded in a continuous manner, wherein the fiber mesh provides flexibility for rolling and rigidity and flatness upon opening of the display. In one embodiment the fiber mesh is bonded to the display with various joining methods such as using epoxy glue.

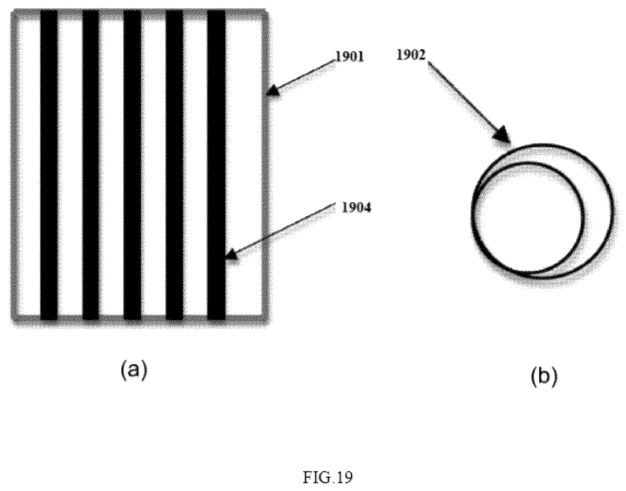

FIG. 19 (a) shows a schematic of an exemplary foldable display structure comprising a display 1901 and a structural component comprising a set of longitudinally aligned ribbons 1904 comprising an amorphous alloy (e.g., bulk solidifying amorphous alloy or amorphous ribbons). FIG. 6 and FIG. 7 as described herein provide the structure comprising multiple layers for each of longitudinally aligned ribbons 1904. The ribbons may have a thickness of between about 1 μm and 2.0 mm—e.g., between about 0.02 mm and about 1.5 mm, between about 0.03 mm and about 1.0 mm, between about 0.05 mm and about 0.5 mm, between about 0.1 mm and about 0.4 mm, between about 0.2 mm and about 0.3 mm. The ribbons may have a width of between about 0.5 and about 20.0 mm—e.g. between about 1.0 mm and about 15 mm, between about 2.0 mm and about 10 mm, between about 4.0 mm and about 8.0 mm, between about 5.0 mm and about 6.0 mm. The ribbons may be extended to the edge of the display or may be extended further outward of the edge of the display. In this embodiment, the display may be folded in a continuous manner, wherein the ribbons may provide flexibility for rolling and rigidity and flatness upon opening of the display. In one embodiment the ribbon mesh is bonded to the display with various joining methods such as using epoxy glue.

In some embodiments described herein, the terms “ribbons” and “fibers” refer to highly flexible components, each of which may be folded (as shown in 1902 in FIG. 19 (b)) into a diameter in the range of about 10 mm to about 100 mm (e.g., about 20 mm to about 80 mm, about 40 mm to about 60 mm), whereas the terms “strips” and “wires” refer to relatively rigid components, each of which can be folded into a diameter larger than 30 mm (e.g., larger than 40 mm, 50 mm, 60 mm, or larger).

Due at least in part to the desired properties as described above, the FDS described herein may be employed as a component of a variety of devices, including an electronic device. An electronic device herein may refer to a mobile phone, smart phone, PDA, computer (e.g., laptop, desktop, tablet computer, etc.), television, and various wall-mountable displays. A device may contain a plurality of the FDSs described herein. In one embodiment, multiple FDSs may be joined together to form one large display. For example, FDS of a small size (e.g., smaller than a pre-existing personal reader or tablet computer) may function as secondary displays off one device (e.g., smartphone). In one embodiment wherein the FDSs are a part of a smartphone, one FDS may be used to perform navigation function while another to read email, and at the same time the smart phone may be used for talking—this may be done with one data plan as well. In another embodiment, at home or in office, one “connected” device may be used to drive multiple FDSs, some as TVs, some as computers, and some as communication devices simultaneously, sequentially, or both. In at least one embodiment, the display structures described herein are more desirable due to their extreme light weight, flexibility and being less prone to breakage, in comparison to the pre-existing glass-based displays such as LCD (Liquid Crystal Displays).

Method of Making: Another aspect of the embodiments described herein provides a method of making a foldable display structure, such as one in near-net shape form, which display structure comprises a display comprising an organic material and at least one structural component comprising at least one amorphous alloy. The display and the structural component may be any of those described above.

One embodiment provides a method of making a foldable display structure, the method comprising: providing a feedstock of amorphous alloy being substantially amorphous and having an clastic strain limit of about 1.5% or greater and a ΔT of 30° C. or greater; heating the feedstock to around the glass transition temperature; shaping the heated feedstock into the desired near-net shape of foldable display structure; and cooling the formed part to temperatures far below the glass transition temperature. As described above, ΔT refers to the difference between the onset of crystallization temperature, Tx, and the onset of glass transition temperature, Tg, In one embodiment, a temperature around glass transition refers to a temperature that can be below glass transition, at or around glass transition, and above glass transition temperature, but always at a temperature below the crystallization temperature Tx. The cooling step may be carried out at rates similar to the heating rates at the heating step. Alternatively, it may be carried out at rates greater than the heating rates at the heating step. The cooling step may also be achieved while the forming and shaping are maintained.

One embodiment provides a method of making a foldable display structure, the method comprising: providing a homogeneous alloy ingot (not necessarily fully or partially amorphous); heating the feedstock to a casting temperature above the melting temperatures; introducing the molten alloy into the die cavity having the near-net shape of foldable display structures and quenching the molten alloy to temperatures below glass transition.

One embodiment provides a method of making a foldable display structure, the method comprises assembling a display with at least one structural component. The assembling may involve disposing and/or joining at least one structural component over a portion of the display. As described above, the joining may involve gluing together (e.g. with epoxy glue) the display and at least one structural component. One advantage of the methods described herein is that the assembling of the components of the foldable display structure may involve no (or minimal) use of fasteners.

In one embodiment wherein the display structures provided herein have a substrate and a display, the structural component may be disposed over (or directly on) the substrate during production of the substrate. The substrate may contain any material, including those used in pre-existing displays, such as plastics, glass, etc. Because an amorphous alloy (of the structural component) may withstand higher temperatures than most plastics and synthetic substrate material, synthetic material may be poured over the structural component to form an intimate bond. The bond may be chemical, physical, or both. An intimate bond may refer to a bond that has very little observable gap between the bonded components, and in some instances, as a result, the components may not separate easily. Alternatively, structural component(s) may be provided between two sticky substrate materials so that all of these may be bonded.

The at least one structural component may be made by a method comprising: heating a feedstock comprising an alloy that is at least substantially amorphous to a first temperature that is greater than or equal to a glass transition temperature (Tg) of the alloy; forming the heated feedstock into a preform; and cooling the preform to a second temperature lower than the Tg to form the at least one structural component.

The feedstock may comprise an alloy that is at least partially, such as at least substantially, such as completely, amorphous. The method may further include a method of making an alloy feedstock. The method of making an alloy feedstock may include heating at least one ingot comprising an alloy that is at least partially not amorphous to a third temperature that is higher than or equal to a melting temperature (Tm) of the alloy; and cooling the heated ingot at a rate that is sufficient to form the feedstock comprising an alloy that is at least substantially amorphous. The ingot may comprise a mixture of elements to be alloyed to form the feedstock. The ingot may be homogeneous (although it need not be) with respect to the chemical composition of the elements of the alloy mixture but may not be of an amorphous phase. The cooling rate during the making of the feedstock may be fast enough to bypass the crystallization formation region in the Time-Temperature-Transformation (TTT) diagram to avoid formation of a crystalline phase, thereby forming a feedstock that is at least partially amorphous.

In one embodiment, during the process of making a foldable display structure, the heated feedstock is formed into a preform before the preform is cooled to form the final structural component of the display structure. The forming may include, for example, shaping the preform into a desired shape. This process may involve any techniques known in the art. For example, this may involve die casting, involving introducing the feedstock into a cavity of a die to form a preform. In some embodiments, the forming may involve shaping the feedstock into the preform with pressure. The pressure may be mechanical pressure, for example by hand, tool, or air pressure. The preform may be near-net shape of the structural component. In other words, no (or minimal) additional processing would be needed to shape the preform into the desired shape of the structural component. In some embodiments, certain post-processing, such as certain surface treatments, may be employed. For example, surface treatment may be employed to remove oxides from the surface. Chemical etching (with or without masks), as well as light buffing and polishing operations, may also be employed to improve the surface finish.

The near-net shape of the structural component of the display structures during the processes described herein is one distinguishing feature compared to the pre-existing process. Specifically, the preferred material of the pre-existing process, which employs shape-memory Ti—Ni alloys and/or spring steels, may only be produced in very limited shapes and forms, such as wires and flat strips because of the difficulty thereof to produce near-net shaped products. By contrast, the near-net shape forming ability of amorphous alloys, particularly bulk solidifying amorphous alloy, of the processes described herein allow fabrication of intricate foldable display structures with high precision and reduced processing steps. Additionally, this may also allow minimal use of bending and welding, which can reduce the structural performance and increase manufacturing costs and aesthetic defects. In one embodiment, producing foldable display structures in near-net shape form may significantly reduce the manufacturing costs while still forming foldable display structures with intricate features, such as precision curves, and a high surface finish on aesthetically sensitive areas. Also, not to be bound by any particular theory, but (bulk solidifying) amorphous alloys retain their fluidity from above the melting temperature down to the glass transition temperature due to the lack of a first order phase transition. This is distinguishable from conventional crystalline metals and alloys, or even certain amorphous alloys in some instances. Because amorphous alloys retain their fluidity, they do not accumulate significant stress from their casting temperatures down to below the glass transition temperature. Thus, dimensional distortions from thermal stress gradients can be minimized.

Exemplary Embodiments: In one embodiment, the foldable display structure comprises at least one part made of bulk solidifying amorphous alloy or amorphous alloy ribbons.

In another embodiment, the foldable display structure comprises longitudinally aligned ribbons or fibers substantially made of bulk solidifying amorphous alloy or amorphous ribbons and attached to the back (substrate side) of the OLED display.

In another embodiment, the foldable display structure comprises horizontally aligned ribbons or fibers substantially made of bulk solidifying amorphous alloy or amorphous ribbons and attached to the back of the OLED display.

In still another embodiment, the foldable display structure comprises a mesh of ribbons or fibers substantially made of bulk solidifying amorphous alloy or amorphous ribbons and attached to the back of the OLED display.

In still another embodiment, the foldable display structure comprises a set of ribbons or fibers substantially made of bulk solidifying amorphous alloy or amorphous ribbons and joined to the back of the OLED display.

In still another embodiment, the foldable display structure comprises diagonally crossing and rigid strips or wires substantially made of bulk solidifying amorphous alloy or amorphous ribbons and attached to the back of the OLED display.

In one embodiment, the foldable display structure is at least partially made of a Zr—Ti base bulk solidifying amorphous alloy or amorphous ribbons.

In another embodiment, the bulk solidifying amorphous alloy or amorphous ribbons in the foldable display structure is Be free.

In another embodiment, the foldable display structure is at least partially made of a Zr/Ti base bulk solidifying amorphous alloy or amorphous ribbons with in-situ ductile crystalline precipitates.

In another embodiment, a molten piece of bulk solidifying amorphous alloy or amorphous ribbons is cast into a near-net shape manufactured foldable display Structure.

In another embodiment, a stock feed of bulk solidifying amorphous alloy or amorphous ribbons is molded into a near-net shape manufactured foldable display Structure.

In another embodiment, at least part of a near-net shape manufactured foldable display structure is formed by casting or molding the bulk solidifying amorphous alloy.

In another embodiment, the near-net shape manufactured foldable display structure is a near-net shape molding component.

In another embodiment, the near-net shape manufactured Foldable display structure is a near-net shape cast component.

One embodiment provides a method of fabricating a near-net shape manufactured foldable display structure comprising the following steps: providing a feedstock of molten alloy at above Tm; introducing the molten alloy to a die cavity having the near-net shape of foldable display Structure; quenching and taking the part out of the die cavity; and final finishing.

Another embodiment provides a method of fabricating a near-net shape manufactured foldable display structure comprising the following steps: providing a feedstock of alloy that is at least partially amorphous; heating the feedstock to above Tg but below Tx, shaping the heated feedstock into desired near-net shape foldable display structure; cooling; and final finishing.

Another embodiment provides a foldable display structure comprising bulk solidifying amorphous alloys or amorphous ribbons.

Another embodiment provides a method of making foldable display structure in a near-net shape form comprising bulk solidifying amorphous alloys or amorphous ribbons.

Another embodiment provides a foldable display structure having a structure substantially made of bulk solidifying amorphous alloys or amorphous ribbons, wherein the structural components are secured without the use of fasteners.

According to an embodiment, it is a method for manufacturing comprising: selecting number of layers to form a plurality of layers based on a predetermined thickness of a flexible display apparatus; selecting thicknesses of each of the layers of the plurality of layers; selecting material for each layer such that an elastic limit of the material is at least 1.5% strain; positioning the layers in a desired configuration; and securely connecting the layers such that each layer is connected to at least one other layer at a predetermined position forming a connection; and wherein the flexible display apparatus is part of a display of an electronic device; and wherein each layer of the plurality of layers comprises a rotational degree of freedom and glides relative to an adjacent layer of the plurality of layers about an axis of fold or roll when the display is folded or rolled.

According to an embodiment of the method for manufacturing, the connection is a rigid connection point. According to an embodiment of the method for manufacturing, the connection comprises a mechanical joint comprising one of a spot welding, a fastening joint, and a rivet. According to an embodiment of the method for manufacturing, the connection comprises a mechanical joint comprising a telescopic sliding joint.

U.S. Pat. No. 11,183,651B2, titled “Electronic apparatus”, which is herein incorporated in its entirety, attempts to provide an electronic device having improved reliability against stress caused by bending. The electronic apparatus EA includes a first member MB1, a second member MB2, a third member MB3, a first adhesive member AM1, and a second adhesive member AM2.

U.S. Pat. No. 9,029,846B2 titled “Display apparatus having improved bending properties and method of manufacturing same” which is incorporated herein in its entirety, attempts for a display apparatus having improved bending properties, wherein the display apparatus disclosed includes: a display module including a flexible substrate, a display panel, and an encapsulation film; a lower module disposed below the display module; an upper module disposed on the display module; and an elasticity-adjusting layer, which includes an adhesive material, disposed on or below the display module to adjust a position of a neutral plane in bending of the display apparatus, wherein an elastic modulus of the elasticity-adjusting layer is less than that of at least one of the display module, the lower module, or the upper module, so as to position the neutral plane within or proximate to the display module.

In the above prior art, attempts have been made for reducing bending stress in foldable displays by having an adhesive layer between the layers. Having an adhesive layer between the layers binds the layers together and still moves them together as a single solid piece when a force is applied. Apart from the supporting structure which is explained in the current disclosure, the electronics and controls, enclosures, for display screens remains similar in nature and operation as that of the prior art patents.

The descriptions of the one or more embodiments are for purposes of illustration but are not exhaustive or limiting to the embodiments described herein. Many modifications and variations will be apparent to those of ordinary skill in the art without departing from the scope and spirit of the described embodiments. The terminology used herein best explains the principles of the embodiments, the practical application and/or technical improvement over technologies found in the marketplace, and/or to enable others of ordinary skill in the art to understand the embodiments described herein.

### INCORPORATION BY REFERENCE

All references, including granted patents and patent application publications, referred herein are incorporated herein by reference in their entirety.
U.S. Pat. No. 10,035,184B2, titled, “Material for eyewear and eyewear structure”.
U.S. Pat. No. 10,280,493B2, titled, “Foldable display structures”.
U.S. Pat. No. 10,301,708B2, titled, “Foldable display structures”.
U.S. Pat. No. 10,697,049B2, titled, “Foldable display structures”.
U.S. Pat. No. 9,710,020B2, titled “Rollable display apparatus”.
U.S. Pat. No. 10,459,489B2 titled “Display panel and display apparatus including the same”.
U.S. Pat. No. 10,133,381B2 titled “Display apparatus”.
U.S. Pat. No. 11,183,651B2 titled “Electronic apparatus”.
U.S. Pat. No. 9,029,846B2 titled “Display apparatus having improved bending properties and method of manufacturing same”.

1-45. (canceled)

46. A flexible display apparatus comprising plurality of layers wherein each layer is connected to at least one another layer at a predetermined position forming a connection, wherein the flexible display apparatus is part of a display of an electronic device, and wherein each layer of the plurality of layers comprises a rotational degree of freedom and glides relative to an adjacent layer of the plurality of layers about an axis of fold or roll when the display is folded or rolled.

47. The flexible display apparatus of claim 46, wherein each layer of the plurality of layers comprises a material having an elastic strain limit of at least 1.5%.

48. The flexible display apparatus of claim 46, wherein a flexible silica glass surface forms a first surface layer towards a display side and supported by a second surface layer comprising an amorphous sheet.

49. The flexible display apparatus of claim 48, wherein the amorphous sheet comprises either silica or alloys.

50. The flexible display apparatus of claim 48, wherein an Organic Light-Emitting Diode (OLED) is printed on the flexible silica glass surface and wherein the flexible silica glass surface is firmly bonded to one or more layers of amorphous alloy along a flex zone.

51. The flexible display apparatus of claim 46, wherein at least a layer of the plurality of layers comprises an amorphous material.

52. The flexible display apparatus of claim 51, wherein the amorphous material comprises iron based amorphous ribbons.

53. The flexible display apparatus of claim 51, wherein the amorphous material comprises silica based glass sheets.

54. The flexible display apparatus of claim 52, wherein the iron based amorphous ribbons comprise iron in a first range of 84-100%, silicon in a second range of 0-10%, boron in a third range of 0-5%, and manganese in a fourth range of 0-2%.

55. The flexible display apparatus of claim 52, wherein the iron based amorphous ribbons comprise iron in a first range of 0-100%, cobalt in a second a second range of 0-85%, Nickel in a third range of 0-50%, silicon in a fourth range of 0-10%, molybdenum in a fifth range of 0-8%, boron in a sixth range of 0-5%, and manganese in a seventh range of 0-2%.

56. The flexible display apparatus of claim 52, wherein the iron based amorphous ribbons have a thickness of about 0.023 mm and a width of about 2 mm and about 213 mm.

57. The flexible display apparatus of claim 46, wherein the connection is a rigid connection; and wherein the connection comprises a mechanical joint comprising one of a spot welding, a fastening joint, and a rivet.

58. The flexible display apparatus of claim 46, wherein the predetermined position is configured such that varying the predetermined position varies a degree of free gliding.

59. The flexible display apparatus of claim 46, wherein a first layer of the plurality of layers closer to a display side has a first thickness different from a second layer of the plurality of layers farther from the display side having second thickness, wherein the first thickness is smaller than the second thickness, and wherein an elastic strain limit of a first material of the first layer and a second material of the second layer is at least 1.5%.

60. The flexible display apparatus of claim 46, wherein a magnetic field is used to hold the plurality of layers in stable position, until a force is applied to free the plurality of layers.

61. A display comprising a flexible display apparatus, wherein the flexible display apparatus comprises plurality of layers wherein each layer is connected to at least one another layer at a predetermined position forming a connection, and wherein each layer of the plurality of layers comprises a rotational degree of freedom and glides relative to an adjacent layer of the plurality of layers about an axis of fold or roll when the display is folded or rolled.

62. The display of claim 61, wherein the display is operable to be connected via a wireless connection or a wired connection.

63. The display of claim 61, wherein the display is operable for wireless charging.

64. A method for manufacturing comprising:
selecting number of layers to form plurality of layers based on a predetermined thickness of a flexible display apparatus;
selecting a thickness of each of the layers of the plurality of layers;
selecting material for each layer such that an elastic strain limit of the material is at least 1.5%;
positioning the layers in a configuration; and
securely connecting the layers such that each layer is connected to at least one another layer at a predetermined position forming a connection; and
wherein the flexible display apparatus is part of a display of an electronic device; and
wherein each layer of the plurality of layers comprises a rotational degree of freedom and glides relative to an adjacent layer of the plurality of layers about an axis of fold or roll when the display is folded or rolled.

65. The method for manufacturing of claim 64, wherein the connection is a rigid connection.
